(19) United States
(12) Patent Application Publication
(10) Pub. No.: US 2003/0213619 A1
(43) Pub. Date: Nov. 20, 2003

(54) Ground discontinuity improvement in RF device matching

(76) Inventors: Quentin S. Denzene, Apex, NC (US); Michael L. Martin, Durham, NC (US)

Correspondence Address: COATS & BENNETT, PLLC, P O BOX 5, RALEIGH, NC, 27602, US

(21) Appl. No.: 10/145,211

(22) Filed: May 14, 2002

(51) Int. Cl. H05K 1/11

(52) U.S. Cl. 174/261

(57) ABSTRACT

Device mounting cutouts in PCBs often alter desired characteristic trace impedances by disrupting the continuous low-impedance electrical connection between two or more ground planes that contribute to the control of the trace impedances. Maintaining control of the trace impedances is particularly important in PCBs containing RF devices. Plating one or more inner walls of an RF device mounting cutout with a conductive material in areas proximate to an RF trace enhances RF trace impedance control by establishing a low-impedance electrical connection between the ground planes at the cutout edges. In areas where RF traces contact the conductive plating, notches physically isolating the RF traces from the conductive plating also provide electrical isolation.

### BACKGROUND OF THE INVENTION

The present invention relates generally to circuit board design, and more particularly to multi-layer Printed Circuit Board (PCB) design for Radio Frequency (RF) equipment. Multi-layer PCB design is often challenging simply in terms of fitting the required number of components and their interconnections into physically and economically practical board layers. PCB design becomes decidedly more challenging when signal integrity issues come into play. These issues arise, for example, in circuits that operate at high frequencies or at low noise levels. For such circuits, PCB layout considerations typically include noise isolation, ground integrity, and impedance control.

As an example, RF circuits typically require an RF trace impedance to match an electrically connected RF device impedance. Matching the impedances moderates signal reflections on the RF trace that otherwise compromise signal integrity and reduce power transfer efficiencies. Controlling RF trace impedance requires controlling a number of parameters, including the RF trace width, thickness, and ground plane proximity. Other factors, such as the number and shapes of bends in the trace, and the number and characteristics of plated through holes used to connect ground traces to one or more ground layers within the PCB, referred to herein as vias, also affect trace impedance control.

Conventional PCBs typically use multiple ground planes positioned on different layers of the PCB such that one or more “reference” ground planes lie sufficiently close to RF trace layers of interest to set the RF trace impedance. These reference ground planes generally use multiple vias to connect to a primary ground plane at multiple connection points, such that the reference ground plane serves as an effective, low-impedance continuous ground for the corresponding RF trace layer. Such grounding schemes provide effective impedance control when there are no discontinuities in the ground planes that disrupt the connectivity between the reference ground plane(s) and the primary ground plane.

Many types of RF devices require mounting cutouts, or openings passing through all layers of the PCB, through which the device body extends when mounted on the PCB. Depending on the device size, such PCB openings may be relatively large, resulting in a substantial disruption in the connectivity between reference and primary ground planes, particularly around the perimeter of the device cutout. These disruptions cause ground plane discontinuities that interfere with the ability to control RF trace impedance around the edges of the cutout.

Vias may be used to re-establish low-impedance connectivity between the reference and primary ground planes in the area around the device cutout. However, larger RF devices often require enlarged RF traces, functioning as electrical mounting pads, at the point where the RF device electrically connects to the PCB. Such enlarged pad areas are generally proximate to the device cutout and shadow significant portions of the reference and ground planes along the edge of the cutout. Blind vias, which do not pass completely through the PCB, can interconnect reference and primary ground planes in the shadowed areas; however, such vias add significant manufacturing and verification costs.

### SUMMARY OF THE INVENTION

The present invention provides a method and apparatus for maintaining low-impedance connectivity between two or more ground planes on different layers of a PCB in board areas disrupted by device mounting cutouts. Such connectivity improves impedance control of RF traces that rely on the ground planes for their controlled impedance. In accordance with exemplary embodiments of the invention, plating one or more interior walls of a device cutout with a conductive material electrically connects the ground planes disrupted by the cutout. Thus, the cutout plating serves as a low-impedance connection between the disrupted ground planes.

In one exemplary embodiment, a continuous low impedance path is maintained between the primary ground plane on a first layer of a PCB and a second, inner, RF ground plane layer of the PCB used to determine the characteristic impedance of one or more RF traces on a third layer. The reference and primary ground planes extend to one or more edges of the device cutout, such that plating the cutout connects the two ground planes at the plated edges of the cutout.

In some embodiments, RF traces of interest on an outer layer include device mounting pads that extend to one or more edges of the device cutout. These device mounting pads may abut the cutout and form an inadvertent electrical connection with the cutout plating. Mounting pads manufactured with a small “setback” from the cutout edge may provide one method for avoiding plating contact. Alternatively, notches or other “cutbacks” may be formed at the cutout edges where such contact exists to electrically isolate the mounting pads from the conductive plating.

### BRIEF DESCRIPTION OF DRAWINGS

FIG. 1 illustrates a conventional multi-layer PCB with a cutout for mounting an RF device.

FIG. 2 illustrates a relationship between the physical parameters of a PCB and the characteristic impedance of an RF trace.

FIG. 3 illustrates a selected cross-section of the PCB of FIG. 1.

FIG. 4 illustrates an exemplary embodiment of a PCB according to the present invention.

FIG. 5 illustrates another exemplary embodiment for the PCB of FIG. 5.

FIGS. 6A and 6B illustrate isolation notches in the board of FIG. 5.

FIG. 7 illustrates exemplary notch details.

FIG. 8 illustrates a device mounted in the board of FIG. 5.

### DETAILED DESCRIPTION OF THE INVENTION

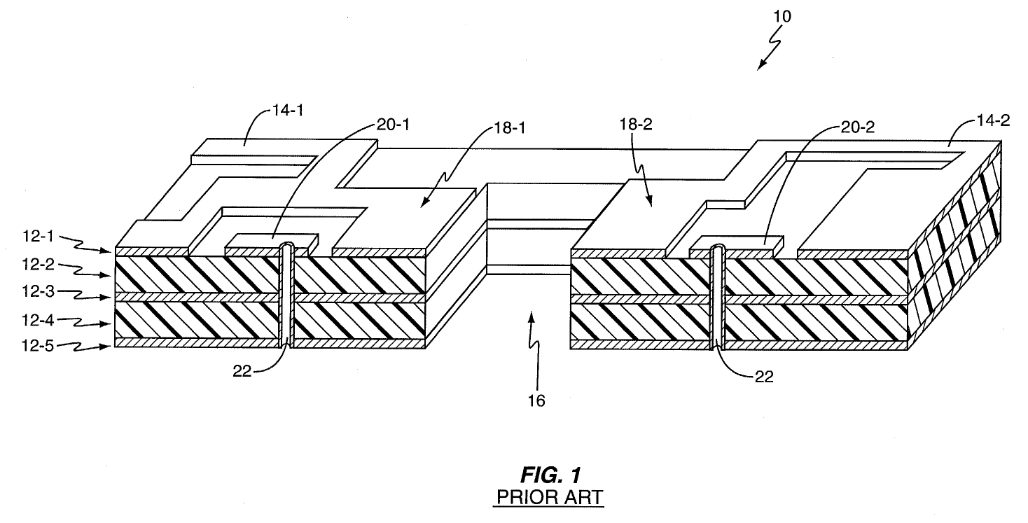

FIG. 1 illustrates a conventional multi-layer PCB, generally represented by the numeral 10. Neither FIG. 1 nor any other figures discussed herein are drawn to scale and, as such, the relative size or proportion of selected board features are exaggerated to aid the discussion. Moreover, actual multi-layer PCBs often comprise complex laminate structures involving a mix of conductive and insulative layers, and may include solder mask layers and other features, not shown. However, the illustration of complex PCB layering details is not relevant to understanding the present invention.

With the above in mind, PCB 10 comprises five layers, including an RF trace layer 12-1, a first dielectric or substrate layer 12-2, a reference ground layer 12-3, a second dielectric layer 12-4, and a primary ground layer 12-5. Layers 12-1 and 12-5 represent the PCB's two outer layers, and may be referred to as top and bottom layers, respectively.

RF trace layer 12-1 includes RF traces 14-1 and 14-2, which include device-mounting areas or pads 18-1 and 18-2, respectively. The pads 18 adjoin a device-mounting cutout 16. An RF device (not shown) mounts to the PCB 10, typically by soldering its leads to the pads 18, with at least a portion of the device's body intended to project into or through the cutout 16. Oftentimes, acceptable performance of the mounted RF device depends on controlling the impedance of RF traces 14. In general, controlling the impedance of RF traces 14 comprises matching the impedance of RF traces 14, including the effects of mounting pads 18, to the impedance of the mounted RF device.

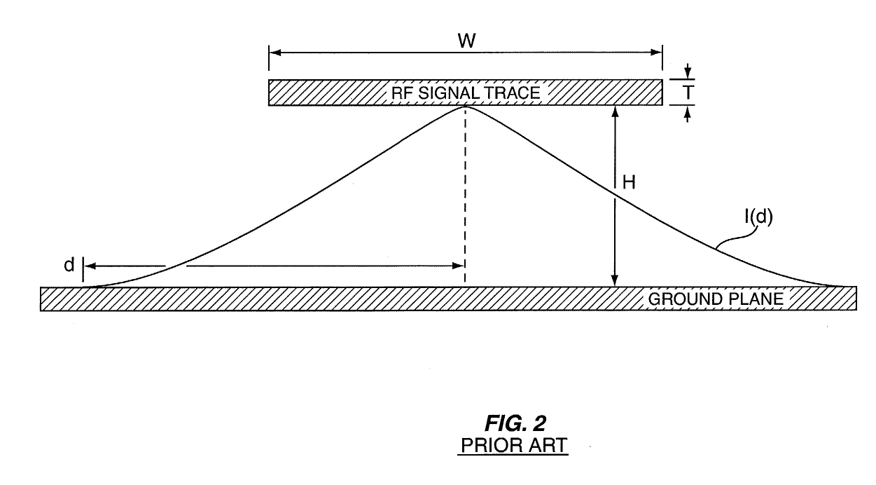

To effectively control RF trace impedance, one must first understand some of the driving design parameters. FIG. 2 illustrates selected relationships between RF trace impedance, RF trace geometry, and the proximity of the RF trace to a ground plane. More particularly, FIG. 2 illustrates the current density distribution, I(d) defined in Equation 1 below, of the RF trace as a function of its height above the ground plane. Equation 2 illustrates the relationship between the trace's physical parameters and its characteristic impedance.

$$\begin{matrix}I ( d ) ∝ \frac{H}{{H}^{2} + {d}^{2}} , & ( 1 ) \\ {Z}_{o} ∝ ln ( \frac{5.98 H}{0.8 W + T} ) , & ( 2 )\end{matrix}$$

For Equations 1 and 2, H=height of the RF trace above the ground plane, d=perpendicular distance from the centerline of the RF trace, W=width of the RF trace, and T=thickness of the RF trace.

As the above equations illustrate, controlling trace impedance depends upon controlling a number of physical parameters, including the proximity of signal ground traces and/or planes relative to the RF trace of interest. FIG. 1 illustrates the use of reference ground layer 12-3, which includes a more or less continuous conductive plane (ground plane), for controlling the impedance of RF traces 14. The reference ground layer's effectiveness in this role relies on it being a continuous low-impedance ground layer sufficiently close to RF trace layer 12-1.

This latter aspect, that of layer 12-3 serving as an effective low-impedance ground layer, depends on the ground plane of layer 12-3 itself being coupled to the PCB's primary signal ground plane on primary ground layer 12-5 through a sufficient number of low-impedance connections. Vias represent a common approach to interconnecting layers of a PCB. In FIG. 1, vias 22 extend through the various layers of PCB 10 and interconnect the ground planes of layers 12-3 and 12-5.

Vias 22 also provide convenient ground connection points for ground traces 20-1 and 20-2 residing on trace layer 12-1. Ground traces 20 may be used in controlling the impedance of RF traces 14, connecting surface mount components to ground, and often are further used to reduce cross-talk between parallel runs of signal traces. It should be understood that trace layer 12-1 is rather simplified, and that it might include a large number of RF traces 14 and ground traces 20, along with signal traces of various other types.

The use of vias 22 permits the convenient placement of relatively low-impedance ground connections in close proximity with RF traces 14. In combination with reference ground layer 12-3, such use of low-impedance grounding generally provides an effective approach to trace impedance control. However, relatively large RF trace areas, such as the mounting pads 18-1 and 18-2, present special impedance control challenges.

The RF field maxima that lie along the longitudinal centers of mounting pads 18 are far enough away from the edges of the mounting pads, as measured in the horizontal plane, that ground traces 20 positioned along the mounting pad edge are ineffective in providing the desired signal coupling and RF trace impedance control. One should refer to Equations 1 and 2 above for a better understanding of this ineffectiveness as a function of RF current distribution within the enlarged pad areas 18.

Controlling the impedance in pad areas 18 depends on the ground plane of reference ground layer 12-3 representing a low-impedance, continuous signal ground in the areas shadowed by the pads 18, i.e., those ground plane areas lying directly underneath the pads 18. The cutout 16 disrupts the low-impedance continuous signal ground, which can result in poor connectivity between reference and primary ground planes, 12-3 and 12-5 respectively, around the cutout 16.

One approach to insuring continuous low-impedance connectivity between reference and primary ground layers 12-3 and 12-5 relies, as noted above, on the use of vias 22. However, as vias 22 pass through the entire PCB 10, they are not suitable for ground layer interconnection in the areas underneath mounting pads 18. That is, vias 22 cannot be placed under pads 18 without disrupting the pads.

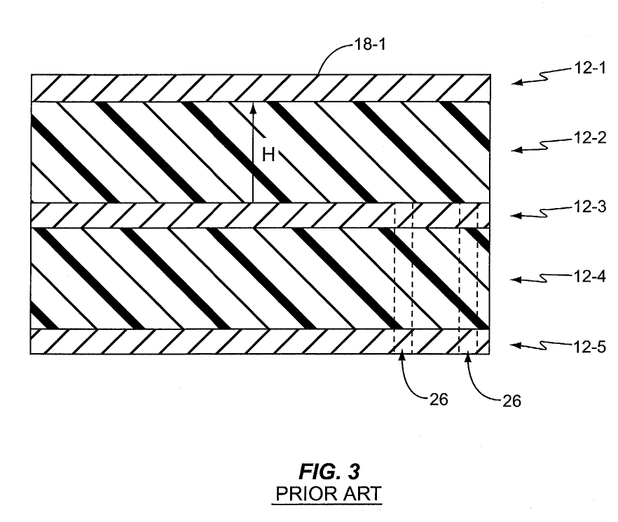

A special type of via, referred to as a “blind” via, provides an alternate solution to traditional vias. Blind vias connect select conductive layers within a PCB, but do not pass completely through all layers of the PCB. FIG. 3 illustrates the use of blind vias 26 to connect the reference and primary ground layers 12-3 and 12-5 in the areas beneath mounting pads 18 without disrupting pads 18. Blind vias 26 provide the continuous low-impedance ground connections underneath pads 18 necessary to control the impedance of traces 14. While effective, blind vias 26 are relatively expensive to manufacture and test. The present invention provides an improved approach to maintaining ground continuity in the presence of device cutouts.

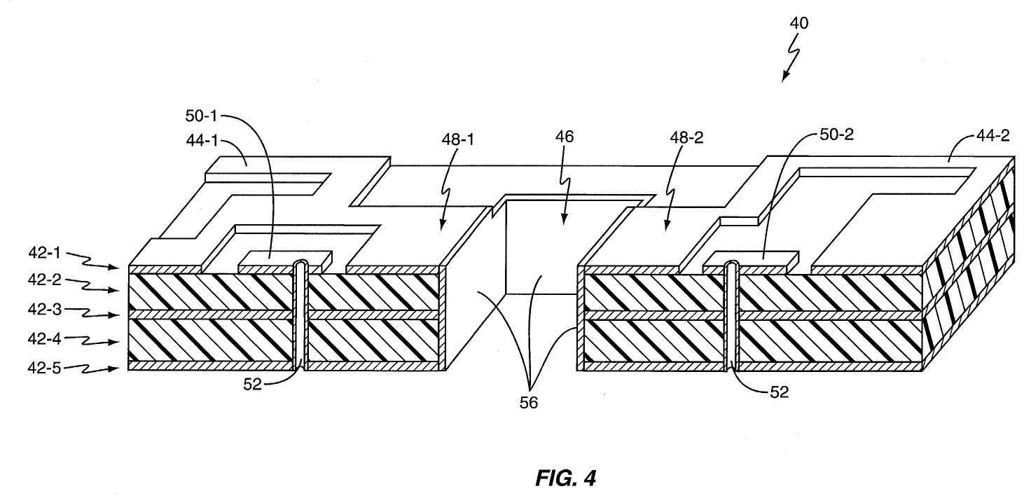

FIG. 4 illustrates an exemplary embodiment of the present invention. PCB 40 comprises five layers, including an RF trace layer 42-1, a first dielectric or substrate layer 42-2, a reference ground layer 42-3, a second dielectric layer 42-4, and a primary ground layer 42-5.

RF trace layer 42-1 includes RF traces 44-1 and 44-2, including device-mounting pads 48-1 and 48-2 adjoining a device mounting cutout 46. Ground traces 50-1, 50-2 electrically connect to reference ground layer 42-3 and primary ground layer 42-5 through vias 52. In this exemplary embodiment, reference and primary ground layers 42-3 and 42-5 are essentially flush with one or more edges of the dielectric layers 42-2 and 42-4 along the cutout 46.

Plating one or more inner walls of cutout 46 with a conductive plating material 56, such as tin-lead or gold flashing, electrically connects the reference ground layer 42-3 to the primary ground layer 42-5. When applied to one or more of the cutout walls where the ground plane edges are present, the conductive plating 56 electrically connects the ground planes together, thereby establishing a low-impedance ground connection at the cutout. This connection provides a low-impedance return path along the full width of pads 48-1 and 48-2, and restores the ability to effectively control the impedance of traces 44. Conductive plating 56 on all walls of the cutout 46 is not necessary. However, plating all walls may simplify the process and reduce manufacturing costs.

As mentioned previously, actual PCBs often comprise additional layers containing power planes, signal traces, etc., internal to the PCB. The cutout 46 generally disrupts these other layers. Where these layers include other conductive planes or traces adjacent to the cutout edge, inadvertent electrical connections may be made with the conductive plating 56. Under these circumstances, additional measures are necessary to prevent such inadvertent connections to the conductive plating 56. One option is to ensure that all conductive planes or traces that could form an undesirable electrical connection with the conductive plating 56 are “setback” from the edge of the cutout 46 a predetermined distance to prevent such connections.

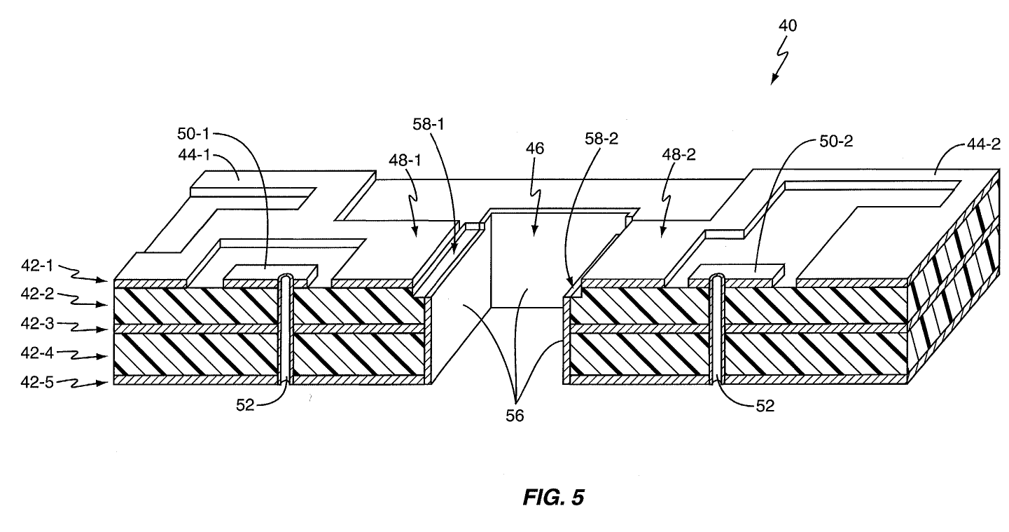

While such setbacks are sufficient for isolating various internal conductive layers from the plating 56, they may not provide sufficient isolation for mounting pads 48 on trace layer 42-1 adjacent to the cutout. Here, small deflections of the leads of an RF device (not shown) inserted through cutout 46 could electrically short to the edge of the conductive plating 56 that extends to the top of the cutout 46. FIG. 5 illustrates an exemplary method of isolating the conductive plating 56 from the mounting pads 48 and the leads of the RF device (not shown). Notches 58-1 and 58-2 formed at the edges of the cutout 46, where the pads 48 abut the edges of the cutout, electrically and physically isolate the conductive plating 56 from mounting pads 48. Further, notches 58 ensure isolation between the plating 56 and the leads of an RF device mounted to pads 48.

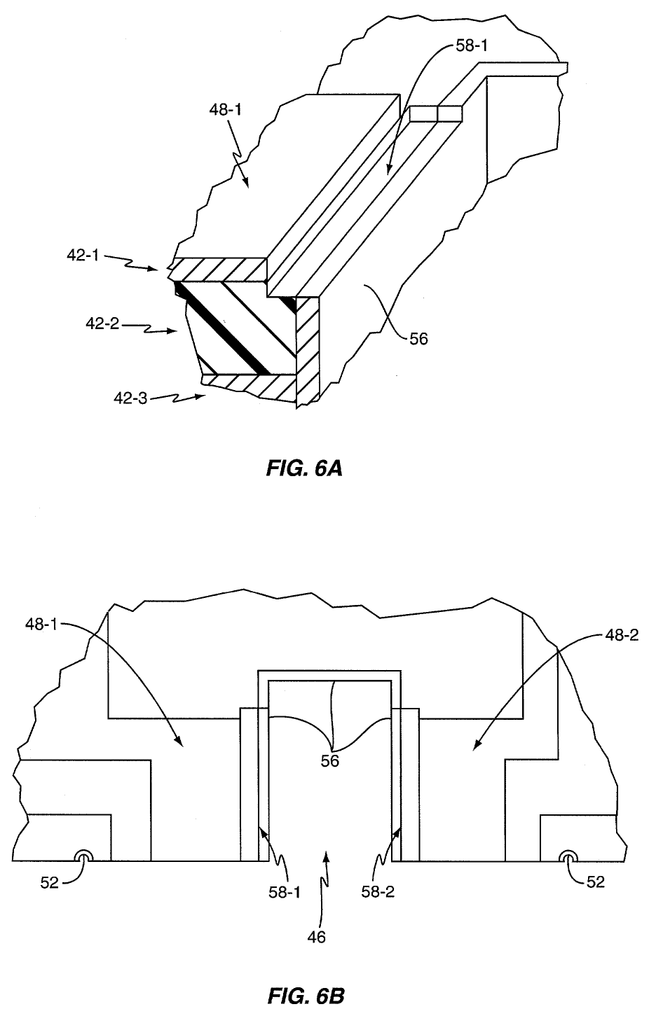

FIGS. 6A and 6B illustrate details of notch 58-1 for further discussion. As seen in FIG. 6A, notch 58-1 cuts completely through the thickness of conductive plating 56 and the height of mounting pad 48-1. FIG. 6B illustrates a top view of a portion of the PCB 40. Note that notch 58-1 may cut beyond the boundaries of the mounting pad 48-1 and the conductive plating 56, and into the dielectric layer 42-2. Removing the additional dielectric material ensures electrical isolation between mounting pad 48-1 and the conductive plating 56.

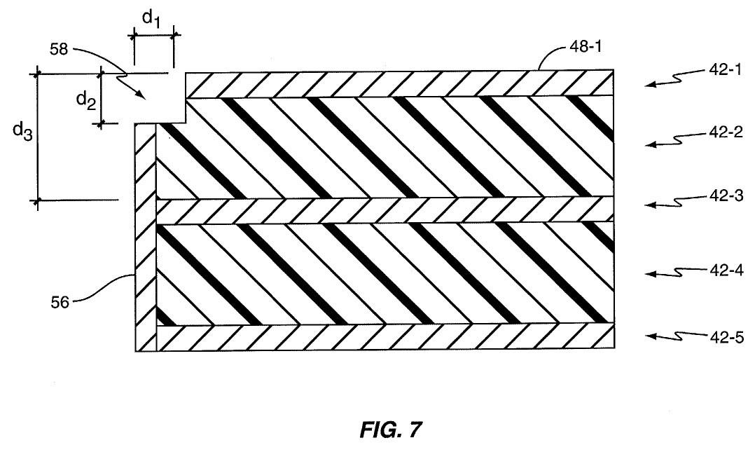

FIG. 7 provides further exemplary details for notch formation. A vertical distance d₃ represents the distance between the top of mounting pad 48-1 and the top of the reference ground layer 42-3. Generally, a milling machine cuts into layers 42-1 and 42-2 of the PCB 40 along the conductive plating 56 proximate to the mounting pad 48-1. The milling procedure cuts through the height of the mounting pad 48-1 and into dielectric layer 42-1 a distance d₂, where d₂<d₃, while simultaneously cutting through the thickness of the conductive plating 56 and into dielectric layer 42-1 a distance d₁. Other material removal techniques, such as laser cutting or etching, can also be employed to form notches 58.

Conductive plating and traces are typically 0.0007″ to 0.0028″ thick. In an ideal implementation, d₁ would be just slightly larger than the thickness of the conductive plating, and d₂ would be just slightly less than d₃. However, machining tolerances as well as tolerances in the thickness of the traces, the dielectric layers, and the conductive plating, generally require a compromise of notch dimensions. Exemplary implementation dimensions are d₁≅0.008″, d₂≅0.006″, and d₃≅0.012″. Of course, these parameters will vary across different designs and technologies.

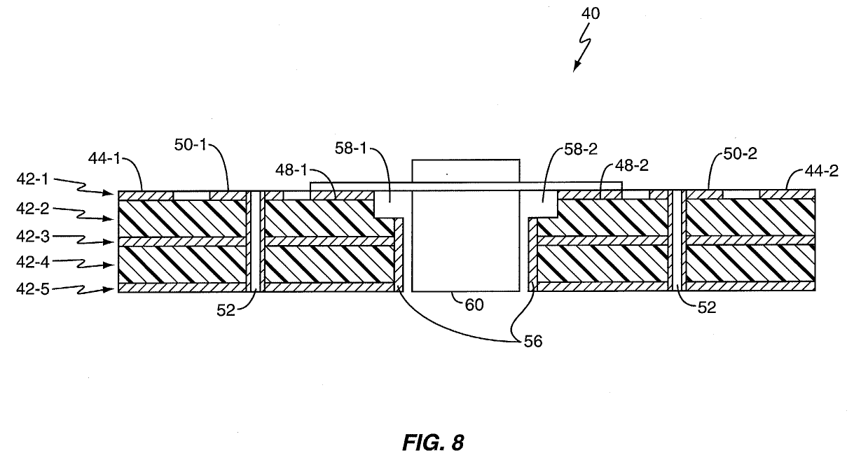

FIG. 8 illustrates a side view of an RF device 60 electrically connected to pads 48 and mounted in the plated cutout 46 of multi-layer PCB 40. Here, the exaggerated thickness and relative proportions clarify how notches 58 isolate the mounting pads 48 from the conductive plating 56 and how the conductive plating 56 electrically connects the reference ground plane on the reference ground layer 42-3 to the primary ground plane on the primary ground layer 42-5.

The present invention may, of course, be carried out in other specific ways than those herein set forth without departing from the essential characteristics of the invention. The present embodiments are, therefore, to be considered in all respects as illustrative and not restrictive, and all changes coming within the meaning and equivalency range of the appended claims are intended to be embraced therein.

What is claimed is:

1. A circuit board comprising:
a first layer comprising a first ground plane;
a second layer comprising a second ground plane;
a cutout in the circuit board defining an opening for accommodating a component to be mounted on the circuit board; and
conductive plating on at least one inner wall of the cutout to electrically connect the first and second ground planes at the cutout.

2. The circuit board of claim 1 further comprising an outer layer including one or more device mounting pads for mounting the component on the circuit board.

3. The circuit board of claim 2 wherein the first ground plane provides impedance control for the device mounting pads on the outer layer.

4. The circuit board of claim 2 wherein one or more of the device mounting pads are adjacent to the cutout and wherein the conductive plating is applied to one or more inner walls of the cutout proximate to the adjacent device mounting pads.

5. The circuit board of claim 4, wherein an edge of the cutout is at least partially notched where an adjacent device mounting pad abuts the edge such that the adjacent device mounting pad is electrically isolated from the conductive plating.

6. The circuit board of claim 4 further including at least one notch in the circuit board electrically isolating the adjacent device mounting pads from the conductive plating.

7. The circuit board of claim 4 further including at least one notch in the circuit board electrically isolating leads on a mounted component from the conductive plating.

8. The circuit board of claim 7 wherein the adjacent device mounting pads are set back from one or more edges of the cutout.

9. The circuit board of claim 6 wherein the circuit board includes a dielectric layer beneath the adjacent device mounting pads and wherein the notch intrudes into the dielectric layer.

10. A method of improving ground continuity between first and second ground planes of a circuit board comprising a device cutout, the method comprising plating at least one inner wall of the cutout to electrically connect the first and second ground planes at the cutout.

11. The method of claim 10 wherein the circuit board includes one or more device mounting pads adjacent to the cutout and wherein plating at least one inner wall of the cutout electrically connects the first and second ground planes abutting one or more inner walls of the cutout proximate to the adjacent device mounting pads.

12. The method of claim 11 further comprising forming at least one notch in the circuit board to electrically isolate the adjacent device mounting pads from the conductive plating.

13. The method of claim 11 further comprising forming at least one notch in the circuit board to electrically isolate one or more leads on a mounted component from the conductive plating.

14. The method of claim 12 wherein forming a notch comprises notching a dielectric layer supporting the adjacent device mounting pads.

15. The method of claim 14 wherein notching further comprises cutting through a portion of the conductive plating a desired distance into the dielectric layer beneath the adjacent device mounting pads.

16. A PCB comprising:
a reference ground plane on a first layer of the PCB;
a primary ground plane on a second layer of the PCB;
a cutout through all layers of the PCB, defining an opening for accommodating an RF component to be mounted on the PCB;
wherein the reference ground plane and the primary ground plane abut one or more edges of the cutout; and
conductive plating on at least one inner wall of the cutout to electrically connect the reference and primary ground planes at the cutout.

17. The PCB of claim 16 further comprising one or more device mounting pads for mounting the RF component to the PCB.

18. The PCB of claim 17 wherein one or more device mounting pads abut the cutout and wherein notches along one or more edges of the conductive plating electrically isolate the abutting device mounting pads from the conductive plating.

19. The PCB of claim 17 wherein one or more device mounting pads abut the cutout and wherein notches along one or more edges of the conductive plating prevent a shorting contact between one or more leads on a mounted RF component and the conductive plating.
